(19) United States
(12) Patent Application Publication
(10) Pub. No.: US 2025/0255031 A1
(43) Pub. Date: Aug. 7, 2025

(54) MANUFACTURING PROCESS FOR THIN SILICON OXIDE LAYER

(71) Applicant: SINGAPORE EBANG PTE. LTD., Singapore (SG)

(72) Inventor: Dong HU, Singapore (SG)

(21) Appl. No.: 18/731,226

(22) Filed: May 31, 2024

(30) Foreign Application Priority Data
Feb. 2, 2024 (CN) 202410151393.X

(51) Int. Cl. H01L 31/18

(52) U.S. Cl. CPC H10F 71/137

(57) ABSTRACT

The present invention is applicable to the technical field of solar photovoltaic and provides a manufacturing process for a thin silicon oxide layer comprising the following steps: 1) placing a TOPCon solar cell on a workbench; and 2) laser processing a surface of the TOPCon solar cell by means of a laser processing device emitting a 355 nm nanosecond ultraviolet laser, whereby the silicon oxide layer with a thickness of 1-4 nm is grown on the surface of the TOPCon solar cell. In the manufacturing process for a thin silicon oxide layer provided by the present invention, the silicon oxide layer formed by the laser-induced oxidation technology can effectively protect the underlying material; and by designing the laser processing device, a uniform silicon oxide layer can be fully formed on the surface of the TOPCon solar cell, thereby improving the protection effect.

### TECHNICAL FIELD

The invention belongs to the technical field of solar photovoltaic, and particularly relates to a manufacturing process for a thin silicon oxide layer.

### BACKGROUND OF THE INVENTION

A solar cell, also known as “a solar chip” or “a photoelectric cell”, is a photoelectric semiconductor wafer that directly generates electricity by utilizing sunlight. It can instantly output voltage and generate current in the presence of a circuit as long as the illuminance meets certain illuminance conditions. In physics, it is called solar photovoltaics, abbreviated as photovoltaics.

In order to improve the performance of solar photovoltaic cells, a research method in the prior art includes surface passivation technology, in which deposition is achieved, for example, via the plasma method, particularly the PECVD method (Plasma Enhanced Chemical Vapor Deposition). However, the surface passivation technology has problems such as low efficiency and high cost.

### SUMMARY OF THE INVENTION

The present invention provides a manufacturing process for a thin silicon oxide layer, aiming to solve the above-mentioned problems.

The present invention is implemented by means of a manufacturing process for a thin silicon oxide layer, comprising the following steps:
1) placing a TOPCon solar cell on a workbench; and
2) laser processing a surface of the TOPCon solar cell by means of a laser processing device emitting a 355 nm nanosecond ultraviolet laser, whereby the silicon oxide layer with a thickness of 1-4 nm is grown on the surface of the TOPCon solar cell.

Preferably, the scanning speed and laser power of the laser processing is 400 mm/s and ≥3 W, respectively.

Preferably, the laser processing device comprises:
a rack on which the workbench is horizontally disposed; and
a laser emission unit mounted on the rack and located above the workbench, wherein the laser emission unit comprises:
a mounting plate;
two longitudinally disposed mounting bars mounted on a lower surface of the mounting plate, wherein several laser emitters are mounted on the mounting bars at intervals along their length direction;
a feed mechanism for driving the mounting plate to move horizontally; and
a driving mechanism for driving the two mounting bars to reciprocate longitudinally.

Preferably, the feed mechanism comprises:
a feed lead screw rotatably horizontally mounted on the rack;
a first stepper motor fixed on the rack for driving the feed lead screw to rotate; and
a mounting seat in threaded connection to the feed lead screw, wherein the mounting seat is disposed to be horizontally movable, and the mounting plate is mounted on the mounting seat.

Preferably, the mounting seat is mounted with a movable rod that slides left and right, the mounting plate is fixed at the bottom of the movable rod, a horizontal slide bar is fixed on the movable rod above the mounting plate, the slide bar is slidably connected to the mounting seat, and a power mechanism for driving the movable rod to reciprocate left and right is disposed on the mounting seat.

Preferably, the power mechanism comprises:
a first rotating shaft rotatably mounted on the mounting seat, wherein a rotating disc is fixed on the first rotating shaft;
a pin shaft eccentrically fixed on the rotating disc, wherein a movement-allowing groove for inserting and moving the pin shaft is provided on the movable rod along its length direction; and
a power structure for driving the first rotating shaft to rotate.

Preferably, the power structure comprises:
a second rotating shaft rotatably mounted on the mounting seat, wherein a second gear is fixed on the second rotating shaft, and a fourth gear meshing with the second gear is fixed on the first rotating shaft, the second gear being larger than the fourth gear; and
a first gear fixed on the second rotating shaft, wherein the first gear is smaller than the second gear, a first gear rack that meshes with the first gear is disposed above the first gear, the first gear rack is horizontally fixed on the rack, and the mounting seat is slidably connected to the first gear rack.

Preferably, the driving mechanism comprises:
an inner screw sleeve rotatably mounted on the mounting plate and located in the middle of the two mounting bars, wherein a third gear is fixed on the bottom of the inner screw sleeve, and a second gear rack that meshes with the third gear is fixed on the side wall of the two mounting bars;
an outer screw rod in threaded connection to the inside of the inner screw sleeve, wherein the top of the outer screw rod extends into the movement-allowing groove on the movable rod and is fixed with a slider, and the slider is slidably connected to the groove wall of the movement-allowing groove; and
a compression spring mounted around the outer screw rod, wherein the compression spring is located between the slider and the bottom of the movement-allowing groove.

Preferably, the rack is mounted with an assembly for loading and unloading, the assembly comprising:
a working conveyor belt horizontally mounted on the rack, wherein the workbench is located on a lower side of an upper belt body of the working conveyor belt, the upper belt body of the working conveyor belt, when horizontal, fits to an upper surface of the workbench, and front and rear ends of the workbench extend outside of the working conveyor belt; and
a loading conveyor belt and an unloading conveyor belt mounted on two sides of the working conveyor belt, respectively, wherein the loading conveyor belt is used for delivering the TOPCon solar cell to be processed to the working conveyor belt, and the unloading conveyor belt is used for receiving the processed TOPCon solar cell delivered by the working conveyor belt.

Preferably, pulleys at both ends of the workbench conveyor belt are rotatably mounted on the movable seats that are horizontally slidably connected to the rack, a bidirectional lead screw is rotatably horizontally mounted on the workbench, and a second stepper motor for driving the bidirectional lead screw to rotate is fixed on the rack; and
the bidirectional lead screw runs through the two movable seats, the two movable seats are threadedly connected to two threaded segments of the bidirectional lead screw, respectively, adjustment plates are in threaded connection to the two threaded segments of the bidirectional lead screw at the inner side of the movable seats, the adjustment plates are slidably connected to the rack, and the adjustment plates at both ends are hinged with elastic rods, an end of the elastic rod away from the adjustment plate is hinged with a lower surface of the workbench, and the elastic rod in an initial state is in an upward convex arc and exerts an upward force on the workbench.

Compared with the prior art, the embodiments of the present application mainly have the following beneficial effects:
in the manufacturing process for a thin silicon oxide layer provided by the present invention, the silicon oxide layer formed by the laser-induced oxidation technology can effectively protect the underlying material; and
by designing the laser processing device, a uniform silicon oxide layer can be fully formed on the surface of the TOPCon solar cell, thereby improving the protection effect.

### BRIEF DESCRIPTION OF THE DRAWINGS

FIG. 1 is a flowchart of a manufacturing process for a thin silicon oxide layer provided by the present invention;

FIG. 2 is a structural schematic diagram of a laser processing device used in a manufacturing process for a thin silicon oxide layer provided by the present invention;

FIG. 3 is an enlarged view of A in FIG. 2;

FIG. 4 is a structural schematic diagram of the matching between a third gear and a second gear rack in a laser processing device used in a manufacturing process for a thin silicon oxide layer provided by the present invention; and

FIG. 5 is a structural schematic diagram of a power structure in a laser processing device used in a manufacturing process for a thin silicon oxide layer provided by the present invention.

Annotations to the reference signs in the drawings: 100. workbench; 1. rack; 2. moveable seat; 3. loading conveyor belt; 4. working conveyor belt; 5. elastic rod; 6. adjusting plate; 7. bidirectional lead screw; 8. unloading conveyor belt; 9. first stepper motor; 10. first gear rack; 11. second gear; 12. feed lead screw; 13. rotating disc; 14. slide bar; 15. mounting bar; 16. movement-allowing groove; 17. laser emitters; 18. mounting plate; 19. mounting seat; 20. moveable rod; 21. pin shaft; 22. third gear; 23. second gear rack; 24. inner screw sleeve; 25. outer screw rod; 26. first gear; and 27. fourth gear.

### DETAILED DESCRIPTION OF THE INVENTION

Unless otherwise defined, all technical and scientific terms used herein have the same meanings as those commonly understood by those skilled in the technical field of the present application. The terms used herein in the description of the present application are only for the purpose of describing specific embodiments and are not intended to limit the present application. The terms “comprise” and “have” and any variants thereof in the description and claims as well as the accompanying drawings of the present application are intended to cover non-exclusive inclusion. The terms “first”, “second”, etc. in the description and claims or the accompanying drawings of the present application are used to distinguish between different objects, rather than to describe a specific order.

Reference to “example” herein means that specific features, structures or characteristics described according to the example may be included in at least one example of the present application. The word appearing in various positions in the description does not necessarily refer to the same example, nor is it an independent or alternative example that is mutually exclusive with other examples. Those skilled in the art can explicitly and implicitly understand that the examples described herein can be combined with other examples.

### Example 1

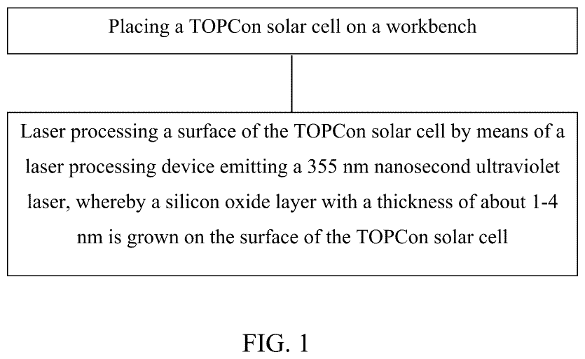

This example of the invention provides a manufacturing process for a thin silicon oxide layer as shown in FIG. 1, comprising the following steps:
1) placing a TOPCon solar cell on a workbench 100; and
2) laser processing a surface of the TOPCon solar cell by means of a laser processing device emitting a 355 nm nanosecond ultraviolet laser, whereby the silicon oxide layer with a thickness of 1-4 nm is grown on the surface of the TOPCon solar cell, and the silicon oxide layer formed by the laser induced oxidation technology can effectively protect the underlying material.

Wherein, the scanning speed and laser power of the laser processing is 400 mm/s and ≥3 W, respectively.

### Example 2

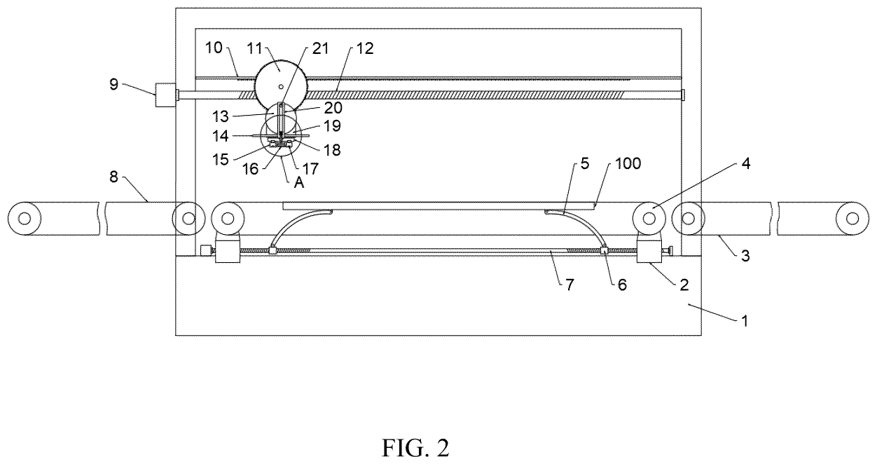

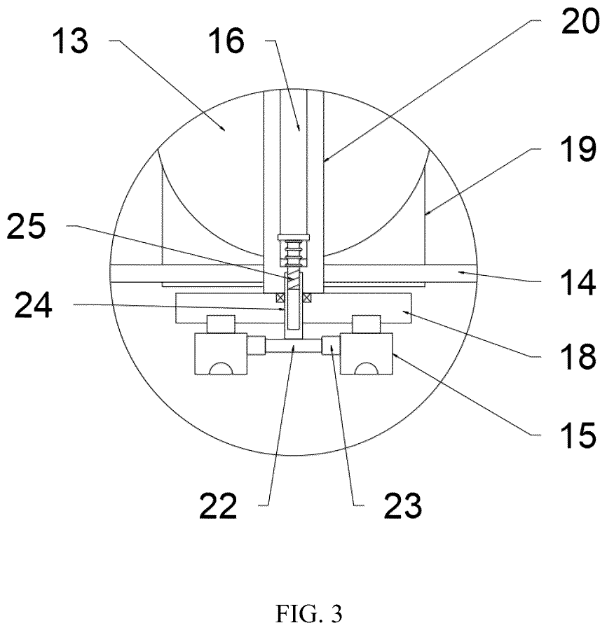

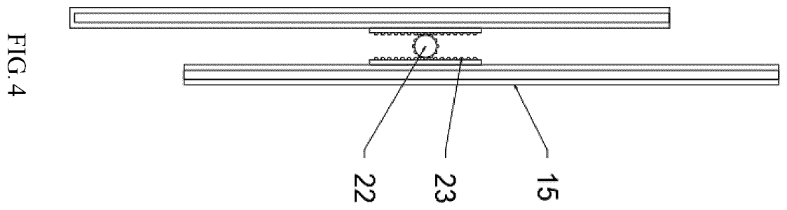

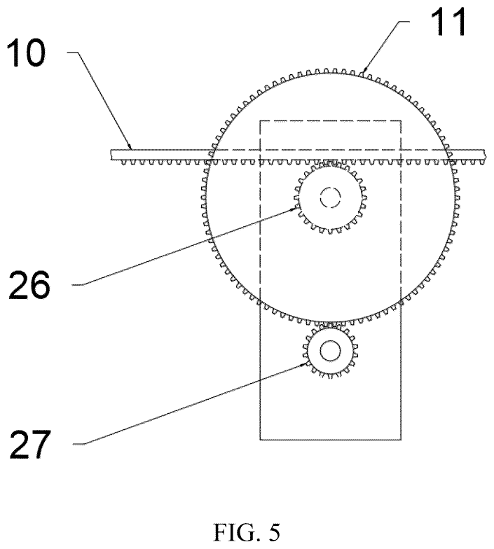

In this example, as shown in FIG. 2 to FIG. 5, the laser processing device applicable to the Example 1 comprises:
a rack 1 on which the workbench 100 is horizontally disposed; and
a laser emission unit mounted on the rack 1 and located above the workbench 100, wherein the laser emission unit comprises:
a mounting plate 18;
two longitudinally disposed mounting bars 15 mounted on a lower surface of the mounting plate 18, wherein several laser emitters 17 are mounted on the mounting bar 15 at intervals along their length direction;
a feed mechanism for driving the mounting plate 18 to move horizontally; and
a driving mechanism for driving the two mounting bars 15 to reciprocate longitudinally.

When working, the TOPCon solar cell is placed on the workbench 100; the laser emitters 17 are turned on to emit a nanosecond ultraviolet laser to irradiate the upper surface of the TOPCon solar cell; the mounting plate 18 is then driven by the feed mechanism to move horizontally; the mounting plate 18 drives the laser emitters 17 on the mounting bar 15 to move horizontally, meanwhile the driving mechanism drives the two mounting bars 15 to reciprocate longitudinally and the mounting bar 15 drives the laser emitters 17 to reciprocate longitudinally. In this manner, TOPCon solar cells of different sizes can be fully laser processed to fully form a silicon oxide layer of uniform thickness.

Wherein, the feed mechanism comprises:
a feed lead screw 12 rotatably horizontally mounted on the rack 1, which can be rotatably mounted through bearings;
a first stepper motor 9 fixed on the rack 1 for driving the feed lead screw 12 to rotate, which can be fixed by bolts, wherein the first stepper motor 9 is preferably a CW/CCW motor, and the output shaft of the first stepper motor 9 can be fixedly connected to an end of the feed lead screw 12 through a coupler; and
a mounting seat 19 in threaded connection to the feed lead screw 12, wherein the mounting seat 19 is disposed to be horizontally movable, and the mounting plate 18 is mounted on the mounting seat 19;
wherein by starting the first stepper motor 9, the first stepper motor 9 drives the feed lead screw 12 to rotate, the feed lead screw 12 drives the mounting seat 19 to be in feed movement, and the mounting seat 19 drives the mounting plate 18 to move;
in this example, the mounting seat 19 is mounted with a movable rod 20 that slides left and right, the mounting plate 18 is fixed at the bottom of the movable rod 20 and can be fixed by welding, a horizontal slide bar 14 is fixed on the movable rod 20 above the mounting plate 18, the slide bar 14 is slidably connected to the mounting seat 19, a chute that is slidably connected to the slide bar 14 can be provided on the mounting seat 19, and a power mechanism for driving the movable rod 20 to reciprocate left and right is disposed on the mounting seat 19;
wherein by the power mechanism driving the movable rod 20 to reciprocate left and right, the movable rod 20 drives the mounting plate 18 to reciprocate left and right, and the mounting plate 18 drives the laser emitters 17 on the mounting bar 15 to reciprocate left and right, thereby repeatedly and fully laser processing the TOPCon solar cell to fully form a silicon oxide layer.

In a specific implementation, the power mechanism comprises:
a first rotating shaft (not shown in the figures) rotatably mounted on the mounting seat 19, wherein a rotating disc 13 is fixed on the first rotating shaft;
a pin shaft 21 eccentrically fixed on the rotating disc 13, which can be fixed by welding, wherein a movement-allowing groove 16 for inserting and moving the pin shaft 21 is provided in the movable rod 20 along its length direction; and
a power structure for driving the first rotating shaft to rotate;
wherein the power structure drives the first rotating shaft to rotate, the first rotating shaft drives the rotating disc 13 to rotate, the rotating disc 13 drives the pin shaft 21 to revolve, and the pin shaft 21 moves in the movement-allowing groove 16 and drives the movable rod 20 to reciprocate left and right.

Preferably, the power structure comprises:
a second rotating shaft rotatably mounted on the mounting seat 19, wherein a second gear 11 is fixed on the second rotating shaft, and a fourth gear 27 meshing with the second gear 11 is fixed on the first rotating shaft, the second gear 11 being larger than the fourth gear 27; and
a first gear 26 fixed on the second rotating shaft, wherein the first gear 26 is smaller than the second gear 11, a first gear rack 10 that meshes with the first gear 26 is disposed above the first gear 26, the first gear rack 10 is horizontally fixed on the rack 1, and the mounting seat 19 is slidably connected to the first gear rack 10, wherein the first gear rack 10 can run through the mounting seat 19;
wherein when the feed lead screw 12 drives the mounting seat 19 to move, the mounting seat 19 drives the first gear 26 to move relative to the first gear rack 10, driving the first gear 26 to rotate, the first gear 26 drives the second gear 11 to rotate through the second rotating shaft, the second gear 11 drives the first rotating shaft to rotate through the fourth gear 27, and the first rotating shaft drives the rotating disc 13 to rotate.

In this example, the driving mechanism comprises:
an inner screw sleeve 24 rotatably mounted on the mounting plate 18 and located in the middle of the two mounting bars 15, which can be rotatably mounted through bearings, wherein a third gear 22 is fixed on the bottom of the inner screw sleeve 24 and can be fixed by welding, and a second gear rack 23 that meshes with the third gear 22 is fixed on the side wall of the two mounting bars 15;
an outer screw rod 25 in threaded connection to the inside of the inner screw sleeve 24, wherein the top of the outer screw rod 25 extends into the movement-allowing groove 16 on the movable rod 20 and is fixed with a slider, and the slider is slidably connected to the groove wall of the movement-allowing groove 16; and
a compression spring mounted around the outer screw rod 25, wherein the compression spring is located between the slider and the bottom of the movement-allowing groove 16;
wherein when moving downwards in the movement-allowing groove 16, the pin shaft 21 collides with the slider and presses down on the outer screw rod 25, the outer screw rod 25 moves downwards and drives the inner screw sleeve 24 to rotate, the inner screw sleeve 24 drives the third gear 22 to rotate, and the third gear 22 drives two mounting bars 15 to move longitudinally through the second gear rack 23; after moving to the lowest position, the pin shaft 21 moves upwards in the movement-allowing groove 16, and drives the outer screw rod 25 to move upwards under the action of the compression spring, the outer screw rod 25 drives the inner screw sleeve 24 to rotate reversely, the inner screw sleeve 24 drives the third gear 22 to rotate reversely, and the third gear 22 drives two mounting bars 15 to move reversely through the second gear rack 23, thereby achieving the longitudinal reciprocating motion of the two mounting bars 15, so that the mounting bar 15 drives the laser emitters 17 to reciprocate longitudinally.

For the convenience of loading and unloading, the rack 1 is mounted with an assembly for loading and unloading, the assembly comprising:
a working conveyor belt 4 horizontally mounted on the rack 1, wherein the workbench 100 is located on a lower side of an upper belt body of the working conveyor belt 4, the upper belt body of the working conveyor belt 4, when horizontal, fits to an upper surface of the workbench 100, and front and rear ends of the workbench 100 extend outside of the working conveyor belt 4; and
a loading conveyor belt 3 and an unloading conveyor belt 8 mounted on two sides of the working conveyor belt 4, respectively, wherein the loading conveyor belt 3 is used for delivering the TOPCon solar cell to be processed to the working conveyor belt 4, and the unloading conveyor belt 8 is used for receiving the processed TOPCon solar cell delivered by the working conveyor belt 4.

Further, pulleys at both ends of the workbench 100 conveyor belt are rotatably mounted on movable seats 2 that are horizontally slidably connected to the rack 1, a bidirectional lead screw 7 is rotatably horizontally mounted on the workbench 100 and can be rotatably mounted through bearings, a second stepper motor for driving the bidirectional lead screw 7 to rotate is fixed on the rack 1 and can be fixed by bolts, and the bidirectional lead screw 7 runs through the two movable seats 2 that are threadedly connected to two threaded segments of the bidirectional lead screw 7, respectively, adjustment plates 6 are in threaded connection to the two threaded segments of the bidirectional lead screw 7 at the inner side of the movable seats 2, the adjustment plates 6 are slidably connected to the rack 1, and the adjustment plates 6 at both ends are hinged with elastic rods 5, and an end of the elastic rod 5 away from the adjustment plate 6 is hinged with the lower surface of the workbench 100, and as shown in FIG. 1, the elastic rod 5 in an initial state is in an upward convex arc and exerts an upward force on the workbench 100.

When delivered onto the working conveyor belt 4, the TOPCon solar cell is supported by the workbench 100, and when there is a need for adjusting the distance between the workbench 100 and the laser emitters 17, the second step motor drives the bidirectional lead screw 7 to rotate, the bidirectional lead screw 7 drives the movable seats 2 and the adjustment plates 6 to move synchronously, and the adjustment plates 6 drives the workbench 100 to move upwards through the elastic rods 5. In this manner, the upper body of the working conveyor belt 4 is tensioned while the distance between the TOPCon solar cell and the laser emitters 17 is adjusted to meet different processing requirements. After processing is completed, the second step motor is started to rotate reversely, causing the workbench 100 to return to its initial state, and after unloading, loading can be performed again for processing.

In summary, the present invention provides a manufacturing process for a thin silicon oxide layer, and its working principle is as follows:
the TOPCon solar cell is placed on the workbench 100; the laser emitters 17 are turned on to emit a nanosecond ultraviolet laser to irradiate the upper surface of the TOPCon solar cell; the mounting plate 18 is then driven by the feed mechanism to move horizontally; the mounting plate 18 drives the laser emitters 17 on the mounting bar 15 to move horizontally, meanwhile the driving mechanism drives the two mounting bars 15 to reciprocate longitudinally and the mounting bar 15 drives the laser emitters 17 to reciprocate longitudinally. In this manner, TOPCon solar cells of different sizes can be fully laser processed to fully form a silicon oxide layer of uniform thickness.

It should be noted that, regarding the aforementioned examples, for the sake of simplicity of description, they are all described as a series of action combinations. However, those skilled in the art should be aware that the present invention is not limited by the order of the described actions, as certain steps may be performed in other orders or simultaneously according to the present invention. In addition, those skilled in the art should also be aware that the examples described in the description are all preferred examples, and the actions and modules involved may not necessarily be dispensable for the present invention.

In the examples provided in the present application, it should be understood that the disclosed apparatus may be implemented in other ways. For example, the apparatus examples described above are only illustrative, and for example, the division of the above units is only a logical function-based division, and there may be other division methods in actual implementation, such as those in which multiple units or components can be combined or integrated into another system, or some features can be ignored or not executed. Another point is that the mutual coupling or communication connection shown or discussed can be indirect coupling or communication connection between some interfaces, apparatuses, or units, which can be in the form of telecommunications or other means.

The units illustrated above as separate components may or may not be physically separated. The parts shown as units may or may not be physical units, which means that they can be located in one place or distributed across multiple network units. Some or all of the units can be selected according to actual needs to achieve the purpose of the solution in the present examples.

The above examples are only used to illustrate the technical solution of the present invention, rather than to limit the scope of protection of the invention. Obviously, the described examples are only a part, not all, of the examples of the present invention. Based on these examples, all other examples obtained by those of ordinary skill in the art without creative effort fall within the scope of protection of the present invention. Although the present invention has been described in detail with reference to the above examples, those of ordinary skill in the art, as required, can still combine, add, delete, or otherwise adjust the features in each example of the present invention without creative effort while causing no conflicts, thereby obtaining other different technical solutions that do not depart from the concept of the present invention in nature, and these technical solutions also belong to the scope of protection of the present invention.

1. A manufacturing process for a thin silicon oxide layer, comprising the following steps:
1) placing a TOPCon solar cell on a workbench; and
2) laser processing a surface of the TOPCon solar cell by means of a laser processing device emitting a 355 nm nanosecond ultraviolet laser, whereby the silicon oxide layer with a thickness of 1-4 nm is grown on the surface of the TOPCon solar cell.

2. The manufacturing process for a thin silicon oxide layer of claim 1, wherein the scanning speed and laser power of the laser processing is 400 mm/s and ≥3 W, respectively.

3. The manufacturing process for a thin silicon oxide layer of claim 1, wherein the laser processing device comprises:
a rack on which the workbench is horizontally disposed; and
a laser emission unit mounted on the rack and located above the workbench, wherein the laser emission unit comprises:
a mounting plate;
two longitudinally disposed mounting bars mounted on a lower surface of the mounting plate, wherein several laser emitters are mounted on the mounting bars at intervals along their length direction;
a feed mechanism for driving the mounting plate to move horizontally; and
a driving mechanism for driving the two mounting bars to reciprocate longitudinally.

4. The manufacturing process for a thin silicon oxide layer of claim 3, wherein the feed mechanism comprises:
a feed lead screw rotatably horizontally mounted on the rack;
a first stepper motor fixed on the rack for driving the feed lead screw to rotate; and
a mounting seat in threaded connection to the feed lead screw, wherein the mounting seat is disposed to be horizontally movable, and the mounting plate is mounted on the mounting seat.

5. The manufacturing process for a thin silicon oxide layer of claim 4, wherein the mounting seat is mounted with a movable rod that slides left and right, the mounting plate is fixed at the bottom of the movable rod, a horizontal slide bar is fixed on the movable rod above the mounting plate, the slide bar is slidably connected to the mounting seat, and a power mechanism for driving the movable rod to reciprocate left and right is disposed on the mounting seat.

6. The manufacturing process for a thin silicon oxide layer of claim 5, wherein the power mechanism comprises:
a first rotating shaft rotatably mounted on the mounting seat, wherein a rotating disc is fixed on the first rotating shaft;
a pin shaft eccentrically fixed on the rotating disc, wherein a movement-allowing groove for inserting and moving the pin shaft is provided on the movable rod along its length direction; and
a power structure for driving the first rotating shaft to rotate.

7. The manufacturing process for a thin silicon oxide layer of claim 6, wherein the power structure comprises:
a second rotating shaft rotatably mounted on the mounting seat, wherein a second gear is fixed on the second rotating shaft, and a fourth gear meshing with the second gear is fixed on the first rotating shaft, the second gear being larger than the fourth gear; and
a first gear fixed on the second rotating shaft, wherein the first gear is smaller than the second gear, a first gear rack that meshes with the first gear is disposed above the first gear, the first gear rack is horizontally fixed on the rack, and the mounting seat is slidably connected to the first gear rack.

8. The manufacturing process for a thin silicon oxide layer of claim 7, wherein the driving mechanism comprises:
an inner screw sleeve rotatably mounted on the mounting plate and located in the middle of the two mounting bars, wherein a third gear is fixed on the bottom of the inner screw sleeve, and a second gear rack that meshes with the third gear is fixed on the side wall of the two mounting bars;
an outer screw rod in threaded connection to the inside of the inner screw sleeve, wherein the top of the outer screw rod extends into the movement-allowing groove on the movable rod and is fixed with a slider, and the slider is slidably connected to the groove wall of the movement-allowing groove; and
a compression spring mounted around the outer screw rod, wherein the compression spring is located between the slider and the bottom of the movement-allowing groove.

9. The manufacturing process for a thin silicon oxide layer of claim 3, wherein the rack is mounted with an assembly for loading and unloading, the assembly comprising:
a working conveyor belt horizontally mounted on the rack, wherein the workbench is located on a lower side of an upper belt body of the working conveyor belt, the upper belt body of the working conveyor belt, when horizontal, fits to an upper surface of the workbench, and front and rear ends of the workbench extend outside of the working conveyor belt; and
a loading conveyor belt and an unloading conveyor belt mounted on two sides of the working conveyor belt, respectively, wherein the loading conveyor belt is used for delivering the TOPCon solar cell to be processed to the working conveyor belt, and the unloading conveyor belt is used for receiving the processed TOPCon solar cell delivered by the working conveyor belt.

10. The manufacturing process for a thin silicon oxide layer of claim 9, wherein pulleys at both ends of the workbench conveyor belt are rotatably mounted on the movable seats that are horizontally slidably connected to the rack, a bidirectional lead screw is rotatably horizontally mounted on the workbench, and a second stepper motor for driving the bidirectional lead screw to rotate is fixed on the rack; and
the bidirectional lead screw runs through the two movable seats, the two movable seats are threadedly connected to two threaded segments of the bidirectional lead screw, respectively, adjustment plates are in threaded connection to the two threaded segments of the bidirectional lead screw at the inner side of the movable seats, the adjustment plates are slidably connected to the rack, and the adjustment plates at both ends are hinged with elastic rods, an end of the elastic rod away from the adjustment plate is hinged with a lower surface of the workbench, and the elastic rod in an initial state is in an upward convex arc and exerts an upward force on the workbench.
